(19) United States
(12) Patent Application Publication
(10) Pub. No.: US 2020/0106462 A1
(43) Pub. Date: Apr. 2, 2020

(54) DECODING METHOD AND DECODER

(71) Applicant: HUAWEI TECHNOLOGIES CO., LTD., Shenzhen (CN)

(72) Inventors: Tao Zhang, Shanghai (CN); Zheng Zheng, Shanghai (CN); Zheng Du, Shanghai (CN)

(73) Assignee: HUAWEI TECHNOLOGIES CO., LTD., Shenzhen (CN)

(21) Appl. No.: 16/695,835

(22) Filed: Nov. 26, 2019

Related U.S. Application Data
(63) Continuation of application No. PCT/CN2018/088113, filed on May 24, 2018.

(30) Foreign Application Priority Data
May 27, 2017 (CN) 201710391333.5

(51) Int. Cl. H03M 13/39; H03M 13/37

(52) U.S. Cl. CPC H03M 13/3927; H03M 13/3784; H03M 13/3961

(57) ABSTRACT

This application relates to a decoding method and a decoder. The decoding method includes: calculating, based on a path selection result of a second hit group in a current code block to be decoded, LLRs (log-likelihood ratios) of a first bit group in the code block, where the path selection result includes L paths; calculating BMs (branch metrics) of the first bit group based on the LLRs; selecting at least L BMs for each of the L paths; determining PMs (path metrics) of the first bit group based on the at least L BMs and a path selection result of a previous hit group of the first bit group; and determining a path selection result of the first bit group based on the PMs. In an entire decoding process, other phases before the PM calculation phase can be performed in parallel, thereby reducing a decoding delay, and improving decoding efficiency.

### CROSS-REFERENCE TO RELATED APPLICATIONS

This application is a continuation in part of International Application No. PCT/CN2018/088113, filed on May 24, 2018, which claims priority to Chinese Patent Application No. 201710391333.5, filed on May 27, 2017, all of which are incorporated herein by reference in their entireties.

### TECHNICAL FIELD

This application relates to the communications field, and specifically, to a decoding method and a decoder.

### BACKGROUND

A polar code is based on a channel polarization theory in which it is considered that after channel combining, N transmissions of a same channel cause channel polarization, so that capacities of some channels are close to 1, and capacities of the other channels are close to 0, and a larger N indicates a larger ratio of the two types of channels. The polar code is theoretically proved to be a coding scheme that can achieve a channel capacity.

Because of a structured coding scheme of the polar code, an effective decoding algorithm for the polar code is a successive cancellation (SC) algorithm. To be specific, an estimated value of each next bit of a to-be-decoded code block may be determined based on a received signal and an existing bit estimation sequence by calculating a probability of transition to a channel of a next bit being 0 or 1. As a communication rate increases, performance of the single SC algorithm can no longer meet a decoding requirement. Based on the SC algorithm, a successive cancellation list (SCL) algorithm is generated. In the algorithm, L bit sequence paths that have better metrics and that are of a current bit or bit group are stored; and preferred paths for decoding a next bit or bit group are split from the stored L bit sequence paths, the paths are sorted, and a better path is selected.

However, in a decoding process in which the SCL algorithm is used, each time a sequence path is selected for a next bit or bit group, a result obtained after a sequence path of a current bit or bit group is split and sorting is performed needs to be relied on, to be specific, a selection result of a previous bit or bit group needs to be relied on. Therefore, all bits or bit groups need to be serially processed, to form a critical path. Consequently, a relatively high decoding delay and low decoding efficiency are caused.

### SUMMARY

Embodiments of this application provide a decoding method and a decoder, to resolve a problem of a high decoding delay and low decoding efficiency caused in a decoding process in which an SCL algorithm is used.

According to a first aspect of the embodiments of this application, a decoding method is provided. The method includes: calculating log-likelihood ratios (LLR) of a first bit group based on a path selection result of a second bit group in a current code block to be decoded; calculating branch metrics (BM) of the first bit group based on the LLRs, where the BMs include L groups of BMs, the L groups of BMs are in a one-to-one correspondence with L paths, and a quantity of BMs in each group of BMs is 1/L of a total quantity of the BMs; selecting, for each of the L paths, at least L BMs from one group of BMs that corresponds to the path; determining path metrics (PM) of the first bit group based on the at least L BMs corresponding to each of the L paths and a path selection result of a previous bit group of the first bit group; and determining a path selection result of the current bit group based on the PMs.

It can be learned that the BMs of the first bit group are directly obtained based on the second bit group that is a K^{th} bit group located before the first bit group, where all the BMs of the first bit group are calculated without considering the path selection result of the previous bit group of the first bit group. After the path selection result of the previous bit group is obtained, the PMs can be determined based only on the path selection result of the previous bit group of the first bit group and the selected BMs, where the PMs of the first bit group can be obtained by adding the calculated BMs of the first bit group to PMs of the previous bit group of the first bit group, to determine the path selection result based on the PMs. It can be learned that in an entire decoding process, no PM sorting is required, and when the first bit group is decoded, only the path selection result of the previous bit group needs to be obtained in a PM calculation phase of the current bit group, without waiting for completion of path selection for the previous bit group of the first bit group, so that in the decoding process, other phases before the PM calculation phase can be performed in parallel, thereby greatly reducing a decoding delay, and improving decoding efficiency.

In some embodiments, each bit group includes M bits, where M is an integer greater than or equal to 1, and the calculating LLRs of a first bit group in the code block is: calculating 2^{KM-K} LLRs of the first bit group that correspond to each of the L paths, where L is 2^{N}, and N is an integer greater than or equal to 0; and the calculating BMs of the first bit group based on the LLRs may change to calculating L*2^{KM-K} BMs of the first bit group based on the 2^{KM-K} LLRs corresponding to each of the L paths. It can be learned that when the BMs are calculated, for each branch, a half of branches are actually eliminated by default. In this way, a calculation amount can be reduced, and execution efficiency can be improved.

In some embodiments, the selecting, for each of the L paths, at least L BMs from one group of BMs that corresponds to the path may be: selecting, for each of the L paths according to a preset rule, the at least L BMs from 2^{KM-K} BMs corresponding to the path. It can be learned that to obtain L optimal PMs through calculation, at least L PMs need to be calculated for each path, thereby ensuring that finally obtained L PMs are optimal.

In some embodiments, the selecting, for each of the L paths according to a preset rule, the at least L BMs from 2^{KM-K} BMs corresponding to the path may be: performing, for each of the L paths based on values, preset sorting on the 2^{KM-K} BMs corresponding to the path or absolute values of the 2^{KM-K} BMs corresponding to the path, and selecting the L BMs from the 2^{KM-K} sorted BMs according to the preset rule. To further reduce a subsequent calculation amount, when there are L paths, each path are actually corresponding to 2^{KM-K} BMs, but only L BMs are selected from the 2^{KM-K} BMs, so that the calculation amount can be reduced, and the execution efficiency can be improved.

In some embodiments, the determining PMs of the first bit group based on the at least L BMs selected for each of the L paths and a path selection result of a previous bit group of the first bit group may be: obtaining, for any one of the L paths, at least L PMs by adding the at least L BMs corresponding to the path to PMs of the path; and selecting, as the PMs of the first bit group according to a preset rule, L PMs from at least L*L PMs corresponding to the L paths. Therefore, during actual section, only L maximum PMs are selected from the at least L*L PMs, thereby ensuring that the L selected PMs are L optimal PMs in the at least L*L PMs.

In some embodiments, the L maximum PMs may be selected from the L*L PMs in the following manner. Specifically, the selecting L maximum PMs from L*L PMs of the L paths as the PMs of the current bit group includes: grouping the L paths into X path groups, and performing PM comparison on each of the path groups, to obtain L PMs, where each of the path groups includes 2^{Y} paths, and Y is an integer greater than or equal to 0; and selecting the L maximum PMs from (L/2^{Y})*L obtained PMs as the PMs of the current bit group. It can be learned that in this manner, the L*L PMs are grouped first, and then, selection is further performed from the groups. A grouping manner is based on a multiple of 2.

In some embodiments, the preset rule may be: selecting L objects with maximum values from an object set; or selecting L objects with minimum values from an object set; or selecting L objects with maximum absolute values from an object set; or selecting L objects with minimum absolute values from an object set, where the object is a BM or a PM. It can be learned that the preset rule actually includes four cases: selection of a larger value, selection of a smaller value, selection of a larger absolute value, and selection of a smaller absolute value. The four cases respectively correspond to different algorithms, thereby improving scalability of the solutions in the embodiments of this application.

In some embodiments, the second bit group is a start bit group in the code block to be decoded, and the path selection result of the second bit group may be calculated in the following manner: calculating LLRs of the second bit group;

calculating BMs of the second bit group based on the LLRs of the second bit group; selecting L BMs from the calculated BMs of the second bit group; calculating PMs of the second bit group based on the L selected BMs; and determining the path selection result of the second bit group based on the PMs of the second bit group. It can be learned that because of a particularity that the first bit group in the code block to be decoded is ranked first, a path selection result of a bit group that is N bit groups ahead of the first bit group is not required, and certainly, in the embodiments of this application, a path selection result of a bit group that is N bit groups ahead of the second bit group is not required either for the second bit group. To be specific, the first bit group and the second bit group can be decoded in parallel.

According to a second aspect of the embodiments of this application, a decoder is further provided. The apparatus includes at least one unit configured to perform the decoding method according to any one of the first aspect or the implementations of the first aspect.

According to a third aspect of the embodiments of this application, a communications device is further provided. The communications device includes a processor, a transceiver, a memory, and the decoder according to the second aspect of the embodiments of this application.

According to another aspect of this application, a computer-readable storage medium is provided. The computer-readable storage medium stores an instruction, and when the instruction runs on a decoder, the decoder performs the method according to the foregoing aspects.

According to another aspect of this application, a computer program product including an instruction is provided. When the instruction runs on a decoder, the decoder performs the method according to the foregoing aspects.

### BRIEF DESCRIPTION OF DRAWINGS

FIG. 1 is a schematic diagram of channel combining of two channels;

FIG. 2 is a schematic diagram of combining two independent channels W_{N};

FIG. 3 is a schematic flowchart of an SCL algorithm;

FIG. 4 is a diagram of an embodiment of an SCL algorithm;

FIG. 5 is a diagram of an embodiment of a decoding method according to an embodiment of this application;

FIG. 6 is a diagram of an embodiment of a decoding method according to an embodiment of this application;

FIG. 7 is a schematic diagram of an intra-list sorting process and inter-list sorting process in FIG. 6;

FIG. 8 is a diagram of an embodiment of a decoder according to an embodiment of this application; and

FIG. 9 is a diagram of an embodiment of a communications device according to an embodiment of this application.

### DESCRIPTION OF EMBODIMENTS

Embodiments of this application provide a decoding method. In the method, some phases in a decoding process are performed in parallel, thereby greatly reducing a decoding delay, and improving decoding efficiency.

To make persons skilled in the art better understand the technical solutions in this application, the following describes the embodiments of this application with reference to the accompanying drawings in the embodiments of this application.

In the specification, claims, and accompanying drawings of this application, the terms “first”, “second”, “third”, “fourth”, and so on (if any) are intended to distinguish between similar objects but do not necessarily indicate a specific order or sequence. It should be understood that the data termed in such a way are interchangeable in proper circumstances, so that the embodiments described herein can be implemented in other orders than the order illustrated or described herein. Moreover, the term “include” or “contain” and any other variants mean to cover the non-exclusive inclusion, for example, a process, method, system, product, or device that includes a list of steps or units is not necessarily limited to those expressly listed steps or units, but may include other steps or units not expressly listed or inherent to such a process, method, product, or device.

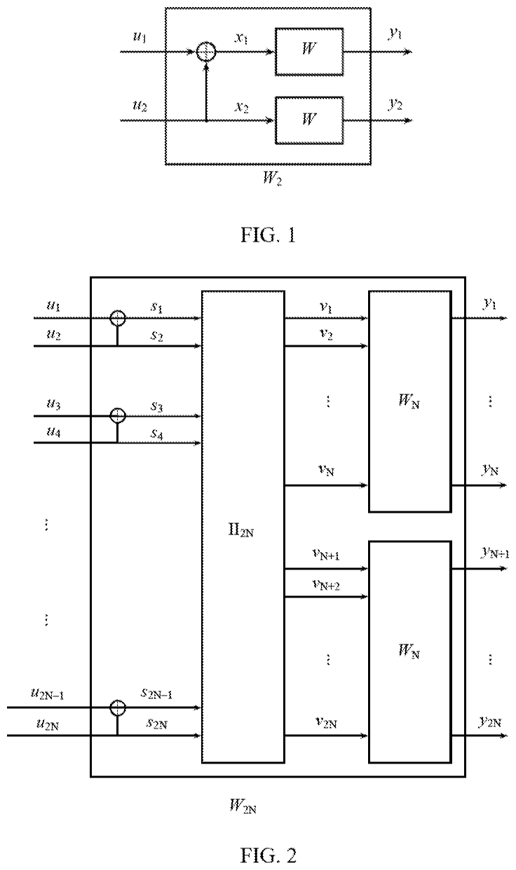

Channel polarization is a process of converting N independent channels into an aggregate channel with a width of N, where N=2ⁿ, and n≥0. The process includes two parts: channel combining (Channel Combining) and channel splitting (Channel Splitting). A larger value of N indicates that a symmetric capacity (Symmetric Capacity) of the channel is closer to 0 or 1. FIG. 1 is a schematic diagram of channel combining of two channels. Two independent channels W are combined, to obtain a channel W₂: X²→Y², where x₁=u₁⊕u₂, and x₂=u₂. On this basis, referring to FIG. 2, FIG. 2 is a schematic diagram of combining two independent channels W_{N}. If the two independent channels W_{N} are combined to generate a channel W_{2N}, an input vector u_{2N} of W_{2N} is first converted into s_{2N}, where for any 1≤i≤N, s₂ᵢ₋₁=u₂ᵢ₋₁⊕u₂ᵢ, and s₂ᵢ=u₂ᵢ. II_{2N} shown in FIG. 2 is a substitution operation, to convert a set s_{N} (s₁, s₂, s₃, and s_{N}) into a set v_{N} (v₁, v₃, . . . , v_{N-1}, v₂, v₄, . . . , and v_{N}).

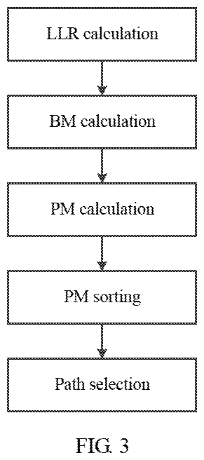

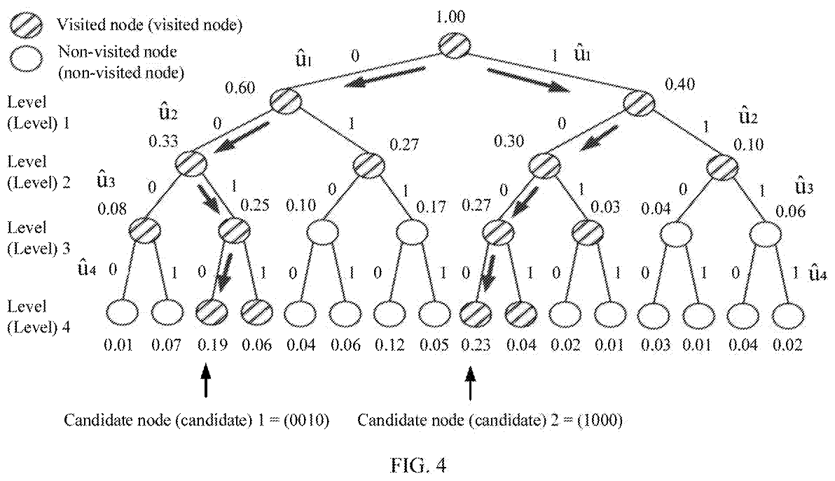

The following describes a decoding process by using an example in which there are two lists, namely, L=2, where L is a quantity of the lists. Decoding is performed bit by bit. For a procedure of an SCL algorithm, refer to FIG. 3. FIG. 3 is a schematic flowchart of an SCL algorithm. Specifically, LLR calculation and BM calculation are performed first; then, PM calculation is performed based on BMs; next, PMs are sorted; and finally, path selection is performed, and a next-round of LLR calculation and BM calculation is performed based on a selection result. The procedure is repeated to complete a decoding process. For a processing process, refer to FIG. 4. FIG. 4 is a diagram of an embodiment of an SCL algorithm, where an arrow direction indicates a path selection process, a filled node indicates a visited node, a non-filled node indicates a non-visited node, and a number above each node except a root node indicates a PM. In a decoding process, an example in which current bits are a first node and a third node at a second level is used. First, BMs of possible nodes at a next level of the first node at the second level are calculated. For the first node at the second level, the BMs of the possible nodes at the next level are a BM of a first node at a third level and a BM of a second node at the third level. Then, that a PM of the first node at the third level is 0.08 and a PM of the second node at the third level is 0.25 is obtained through calculation. Because L=2, the two nodes are both retained without performing exclusion. Next, a third node at the second level is calculated, to obtain a result that a PM of a fifth node at the third level is 0.27 and a PM of a sixth node at the third level is 0.03 through calculation, and the two nodes are also retained. Afterwards, two nodes with larger PMs, namely, the second node at the third level and the fifth node at the third level, are selected from the four nodes as path selection result. Similarly, when decoding is performed bit group by bit group, a quantity of PMs of nodes at a next level that need to be calculated each time is 2^{a}, where a indicates a quantity of bits in a bit group.

It should be noted that when selection is finally performed between two paths, selection is performed based on PM results of all branches. Therefore, the two selected paths may have a same previous bit node.

It should be noted that because an LLR is a signed number, the LLR may be a positive number or a negative number, and a BM calculated based on the LLR may also be a positive number or a negative number.

It can be learned that in the foregoing manner, PMs in all splitting cases of L paths need to be sorted, and only an optimal path can be used as a path for next bit decoding, and the paths need to be sorted during each bit decoding. Consequently, improvement of a throughput of an SCL decoder for a polar code is limited due to sorting and a calculation delay.

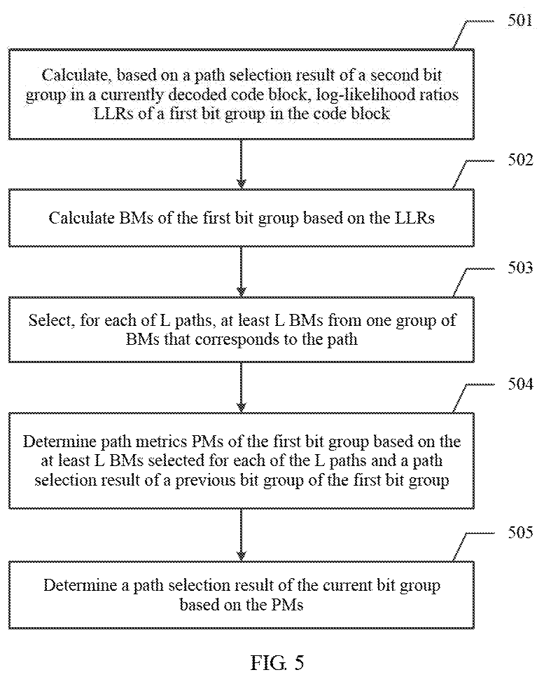

In view of this, an embodiment of this application provides a decoding method. The decoding method is an improvement on the basis of an SCL algorithm, and sequential execution in an original SCL algorithm is changed to parallel execution, thereby improving decoding efficiency. Specifically, FIG. 5 is a diagram of an embodiment of a decoding method according to an embodiment of this application. The method may include the following steps.

501: Calculate, based on a path selection result of a second bit group in a current code block to be decoded, log-likelihood ratios LLRs of a first bit group in the code block.

The second bit group is a K^{th} bit group located before the first bit group in the code block, K is an integer greater than or equal to 2, the path selection result includes L paths, and L is an integer greater than or equal to 1. To be specific, the second bit group in this application is actually a bit group that is N bit groups ahead of the first bit group, and the bit group that is N bit groups ahead of the first bit group may be specifically determined based on performance and decoding efficiency of a decoder.

It should be noted that for any node, an LLR is a logarithm of a ratio of a probability that the node is 0 to a probability that the node is 1.

For the first bit group, if a path selection result of a previous bit group of the first bit group is not considered, different quantities of BMs of the first bit group may be calculated based on a position of the first bit group in the code block to be decoded, and the BMs correspond to BMs of all nodes that may be visited in a first bit group in a binary-tree structure in an SCL algorithm.

It should be noted that a path selection result is actually selecting an optimal path based on PMs. For details, refer to FIG. 4. If L is 2, the path selection result is paths of nodes shown by arrows in FIG. 4. To be specific, the path selection result is L branches in various different branches in a binary-tree in the SCL algorithm or a similar algorithm.

502: Calculate BMs of the first bit group based on the LLRs.

It can be learned that the BMs may be calculated after the LLRs are calculated. For any LLR, two BMs, namely, two branches of 0 and 1 may be calculated.

The BMs include L groups of BMs, the L groups of BMs are in a one-to-one correspondence with the L paths, and a quantity of BMs in each group of BMs is 1/L of a total quantity of the BMs. To be specific, a quantity of BMs of the first bit group is obtained by adding calculated BMs respectively corresponding to the L paths.

The quantity of calculated BMs varies with a quantity of paths and a quantity of bits included in each bit group. If the first bit group and the previous bit group of the first bit group each include M bits, and the quantity of paths is L, the calculating LLRs of a first bit group in the code block may he specifically: calculating 2^{KM-K} LLRs of the first bit group that correspond to each of the L paths, where L is 2^{N}, and N is an integer greater than or equal to 0. In this case, the calculating BMs of the first bit group based on the LLRs may be specifically: calculating L*2^{KM-K} BMs of the first bit group based on the 2^{KM-K} LLRs. To be specific, there are the L*2^{KM-K} calculated BMs of the first bit group in total, to be specific, the L*2^{KM-K} BMs are corresponding to L*2^{KM-K} nodes.

It should be noted that when a bit group includes a plurality of bits, during BM calculation, namely, during calculation of possible results of the current bit group, a half of the possible results can be eliminated. To be specific, if the current bit group includes M bits, there are 2^{M}/2, namely, 2^{M-1} possible results of the current bit group. The following describes a reason for this case, and a BM calculation formula for a plurality of bits in this case is shown below:

$${BM}_{M - 1} = \frac{1}{2} ( {\sum }_{0}^{M - 1} \vert {LLR}_{i} \vert - {\sum }_{0}^{M - 1} ( 1 - 2 \cdot PSUM ) \cdot {LLR}_{i} ) ,$$

where

M indicates a quantity of bits in a bit group, and a PSUM indicates a hard value of an intermediate node. For example, M=4, LLRs are log-likelihood ratios corresponding to all possible results of end bits, the PSUM is a hard value corresponding to each LLR, and the hard value is determined based on a soft value such as an LLR, to be specific, determined as 0 or 1. It can be learned from the foregoing formula that for different BMs of a same path, M/2 paths may be screened out based on sign bits of PSUMs and the LLRs.

503: Select, for each of L paths, at least L BMs from one group of BMs that corresponds to the path.

After the BMs are calculated, a BM selection process may be performed. To ensure that L finally desired optimal BMs can be selected, specifically, when there are L paths, the at least L BMs need to be selected from a group of BMs calculated for each path, to ensure that all L optimal PMs of the first bit group can be calculated based on BMs corresponding to one path that may appear, instead of separately calculating L optimal PMs based on BMs corresponding to a plurality of paths.

It should be noted that a manner of selecting, for each of the L paths according to a preset rule, the at least L BMs from 2^{KM-K} BMs corresponding to the path may be as follows: directly selecting the at least L BMs according to a preset rule, or performing sorting first, and then selecting the at least L BMs according to a preset rule. In either of the selection manners, L optimal BMs obtained when a used algorithm is corresponding to a preset rule are selected. Specifically, the process may be specifically as follows: The at least L BMs are selected, according to the preset rule, from the 2^{KM-K} BMs of the first bit group that correspond to each of the L paths. There are a plurality of preset rules, and the preset rule varies with a used algorithm. For example, X objects are selected from an object set according to the preset rule, where X is an integer greater than or equal to 1, and the preset rule may be X objects with maximum object values in the object set, or may be X objects with minimum object values in the object set, or may be X objects with maximum absolute values of object values, or may be X objects with minimum absolute values of object values. Certainly, the object may be a BM or a PM. A specific case may vary with an algorithm. For example, if an algorithm specifically indicates that a BM with a maximum value is optimal, L maximum BMs are selected. For another example, if an algorithm specifically indicates that a minimum BM is optimal, L minimum BMs are selected. Certainly, if an algorithm specifically indicates that a BM with a maximum absolute value is optimal, L BMs with maximum absolute values are selected. Certainly, if an algorithm specifically indicates that a BM with a minimum absolute value is optimal, L BMs with minimum absolute values are selected.

In addition, a manner of selecting the L BMs through sorting may be as follows: For any one of the L paths, preset sorting is performed on the 2^{KM-K} BMs of the first bit group that correspond to the path or absolute values of the 2^{KM-K} BMs of the first bit group that correspond to the path, and after the preset sorting is completed, the L BMs may be selected, according to one of preset rules required in specific algorithms, from the 2^{KM-K} BMs obtained after the preset sorting.

504: Determine path metrics PMs of the first bit group based on the at least L BMs selected for each of the L paths and a path selection result of a previous bit group of the first bit group.

Because a sorting result of the BMs can reflect a node selection for the current bit group, a node selected for the current bit group can be determined in combination with the path selection result of the previous bit group of the first bit group. Specifically, an example in which the first bit group includes one bit is used, a node corresponding to a previous bit of the first bit group is split into two nodes.

Because all the BMs are sorted before, the two nodes are also sorted. In this case, a larger node may be directly selected, and then a PM of the selected node, namely, a PM of the bit in the current bit group, can be obtained by adding a BM of the selected node to a PM of the node corresponding to the previous bit. Certainly, if the first bit group includes a plurality of bits, the calculated BMs are BMs corresponding to the plurality of bits in the bit group instead of a BM of each of the plurality of bits in the first bit group. For a specific BM calculation manner, refer to the descriptions of step 502, and details are not described herein again.

The following describes a case in which there are L paths, where a value of L is a power of 2. A case in which a bit group includes only one bit and L is 1 is described above, and a process of calculating PMs of the current bit group when L is greater than or equal to 2 and the bit group includes M bits is described below:

First, the L selected paths are determined based on the path selection result of the previous bit group of the first bit group, to be specific, L end nodes of the previous bit group are determined. Then, for any one of the L paths, L PMs are obtained by adding PMs of the path to BMs of the first bit group that correspond to the path. Afterwards, L PMs are selected, as the PMs of the first bit group, from at least L*L PMs of the L paths according to a preset rule.

Optionally, a process of selecting L maximum PMs from the at least L*L PMs of the L paths as the PMs of the first bit group may be as follows:

First, the L paths are grouped into X path groups, and PM comparison is performed on each of the path groups, to obtain L PMs, where each of the path groups includes 2^{Y} paths, and Y is an integer greater than or equal to 0.

Then, the L maximum PMs are selected from (L/2^{Y})*L obtained PMs as the PMs of the current bit group.

For example, L is 8 and Y is 1. To be specific, every two of eight paths are grouped into one group, and a total of four groups are obtained through grouping. (8/2¹)*8, namely, 32 PMs are obtained based on 8*8 PMs through calculation, and then, eight maximum PMs are selected from the 32 PMs. Certainly, the eight maximum PMs may be selected in a plurality of manners. For example, every two of the eight PMs of each of the four groups are compared with each other to obtain 16 PMs, and then the 16 PMs are sorted to obtain the eight final PMs, or the 32 PMs may be directly sorted, and the eight maximum PMs are selected from the 32 PMs. A specific calculation manner may vary with an actual calculation requirement. For example, when L is relatively small, the L*L PMs may be directly sorted. For example, when L is relatively large, grouping is first performed for sorting, and then combined sorting is performed.

505: Determine a path selection result of the current bit group based on the PMs.

It can be learned that after the PMs of the L paths are determined in step 504, path selection can be performed for the current bit group. Because the PMs include the BMs corresponding to the M bits of the current bit group and a path of the previous bit group corresponding to the current bit group, a new path can be selected based on the PMs, and the L paths are selected, to obtain the path selection result of the current bit group.

The following uses two lists as an example to describe an inter-list PM sorting process:

First, each PM in a first list is compared with a corresponding PM in a second list.

Because the BMs are sorted before, after the PMs are calculated, PMs in each list are also sorted. In the SCL algorithm, a bitonic sorting algorithm is usually used. To be specific, for the first list and the second list on which an inter-list algorithm needs to be performed, if sorting is performed on the first list in a monotone-increasing order, sorting is performed on the second list in a monotone-decreasing order; or if sorting is performed on the first list in a monotone-decreasing order, sorting is performed on the second list in a monotone-increasing order. Therefore, in this comparison process, a first PM in the first list is compared with a last PM in the second list, a second PM in the first list is compared with a last but one PM in the second list, and by analog, until a last PM in the first list is compared with a first PM in the second list.

Then, the first L PMs are selected from each of the sorted first list and second list for sorting.

The foregoing step is equivalent to obtaining the first L PMs from each of the first list and the second list. For example, L=8, the selected PMs need to be sorted in this step. The sorting includes three steps: In a first step, a first PM is compared with a fifth PM, a second PM is compared with a sixth PM, a third PM is compared with a seventh PM, and a fourth PM is compared with an eighth PM. Then, in the second step, after the comparison in the first step, a first PM is compared with a third PM, a second PM is compared with a fourth PM, a fifth PM is compared with a seventh PM, and a Sixth PM is compared with an eighth PM. Finally, after the comparison in the second step, a first PM is compared with a second PM, a third PM is compared with a fourth PM, a fifth PM is compared with a sixth PM, and a seventh PM is compared with an eighth PM. In this case, sorting of the eight PMs is completed.

After the eight PMs are sorted, a path of the current bit group may be selected according to a sorting result.

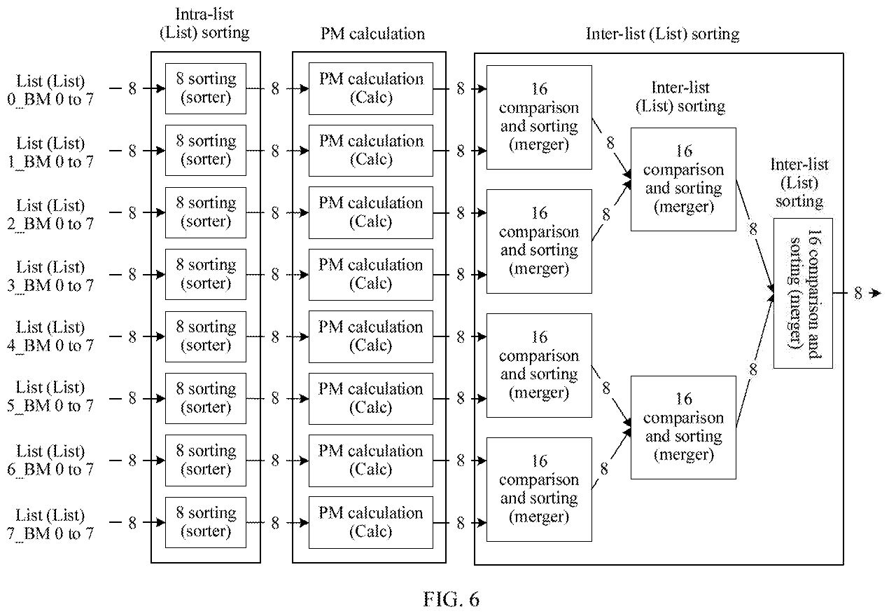

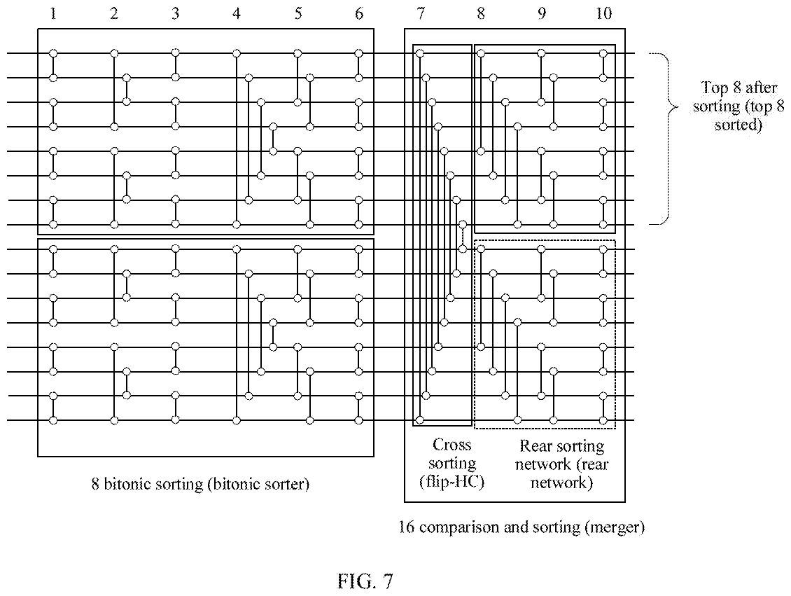

The following describes intra-list BM sorting and inter-list PM sorting in this embodiment of this application by using a specific example. A bitonic sorting algorithm may be used in a process of determining the path selection result of the current bit group based on the PMs. FIG. 6 is a diagram of an embodiment of a decoding method according to an embodiment of this application, and FIG. 7 shows an intra-list sorting process and an inter-list sorting process in FIG. 6. The intra-list sorting is a BM sorting process. For example, there are eight input BMs, and there are eight lists. Sorting is performed on two lists, and an intra-list sorting process is first described. BMs in a first list are B₁₁=0.11, B₁₂=0.21, B₁₃=0.05, B₁₄=0.09, B₁₅=0.03, B₁₆=0.08, B₁₇=0.12, and B₁₈=0.14. BMs in a second list are B₂₁=0.26, B₂₂=0.01, B₂₃=0.33, B₂₄=0.15, B₂₅=0.23, B₂₆=0.35, B₂₇=0.13, and B₂₈=0.18.

a: L BMs in each of the first list and the second list are separately sorted.

This step includes six steps in total. The first list is used as an example for description:

Step 1: First, group every two of the eight BMs in the first list, and sort two neighboring groups in a reverse order, to be specific, compare a first BM with a second BM, compare a third BM with a fourth BM, compare a fifth BM with a sixth BM, and compare a seventh BM with an eighth BM, to obtain B₁₁=0.11 and B₁₂=0.21; B₁₄=0.09 and B₁₃=0.05; B₁₅=0.03 and B₁₆=0.08; and B₁₈=0.14 and B₁₇=0.12.

Step 2: After the sorting in step 1, compare a first BM with a fourth BM, compare a second BM with a third BM, compare a fifth BM with an eighth BM, and compare a sixth BM with a seventh BM, to obtain B₁₃=0.05 and B₁₄=0.09; B₁₂=0.21 and B₁₁=0.11; B₁₅=0.03 and B₁₆=0.08; and B₁₅=0.14 and B₁₇=0.12.

Step 3: After the sorting in step 2, compare a first BM with a second BM, compare a third BM with a fourth BM, compare a fifth BM with a sixth BM, and compare a seventh BM with an eighth BM, to obtain B₁₃=0.05 and B₁₄=0.09; B₁₂=0.21 and B₁₁=0.11; B₁₅=0.03 and B₁₆=0.08; and B₁₇=0.14 and B₁₈=0.12.

Step 4: After the sorting in step 3, compare a first BM with an eighth BM, compare a second BM with a seventh BM, compare a third BM with a sixth BM, and compare a fourth BM with a fifth BM, to obtain B₁₃=0.05 and B₁₄=0.09; B₁₆=0.08 and B₁₅=0.03; B₁₁=0.11 and B₁₂=0.21; and B₁₇=0.14 and B₁₈=0.12.

Step 5: After the sorting in step 4, compare a first BM with a third BM, compare a second BM with a fourth BM, compare a fifth BM with a seventh BM, and compare a sixth BM with an eighth BM, to obtain B₁₃=0.05 and B₁₅=0.03; B₁₆=0.08 and B₁₄=0.09; B₁₁=0.11 and B₁₈=0.12; and B₁₇=0.14 and B₁₂=0.21.

Step 6: After the sorting in step 5, compare a first BM with a second BM, compare a third BM with a fourth BM, compare a fifth BM with a sixth BM, and compare a seventh BM with an eighth BM, to obtain B₁₅=0.03 and B₁₃=0.05; B₁₆=0.08 and B₁₄=0.09; B₁₁=0.11 and B₁₈=0.12; and B₁₇=0.14 and B₁₂=0.21.

Similarly, the second list is sorted according to the foregoing six steps, to obtain B₂₆=0.35, B₂₃=0.33, B₂₁=0.26, B₂₅=0.23, B₂₈=0.18, B₂₄=0.15, B₂₇=0.13, and B₂₂=0.01.

b: Each PM in the sorted first list is compared with a corresponding PM in the sorted second list.

In this step, there are 16 PMs in total in the two lists. To be specific, a first PM is compared with a sixteenth PM, a second PM is compared with a fifteenth PM, a third PM is compared with a fourteenth PM, a fourth PM is compared with a thirteenth PM, a fifth PM is compared with a twelfth PM, a sixth PM is compared with an eleventh PM, a seventh PM is compared with a tenth PM, and an eighth PM is compared with a ninth PM, so that the first eight PMs in the two lists in terms of value are ranked at the first eight positions in a sequence.

c: The first L PMs are selected from each of the sorted first list and second list for sorting.

The sorting includes three steps:

Step 1: Compare a first PM with a fifth PM, compare a second PM with a sixth PM, compare a third PM a seventh PM, and compare a fourth PM with an eighth PM.

Step 2: After the comparison in step 1, compare a first PM with a third PM, compare a second PM with a fourth PM, compare a fifth PM with a seventh PM, and compare a sixth PM with an eighth PM.

Step 3: After the comparison in step 2, compare a first PM with a second PM, compare a third PM with a fourth PM, compare a fifth PM with a sixth PM, and compare a seventh PM with an eighth PM. In this case, sorting of the eight PMs is completed.

d: A path of a current bit group is selected based on a sorting result of the first L PMs.

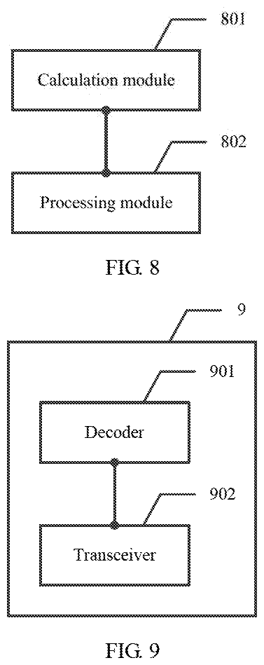

The polar code decoding method in the embodiments of this application is described above. A decoder in the embodiments of this application is described below. FIG. 8 is a schematic diagram of a decoder according to an embodiment of this application. The decoder is applied to polar code decoding, and the decoder includes a calculation module 801 and a processing module 802.

The calculation module 801 calculates, based on a path selection result of a second bit group in a current code block to be decoded, LLRs of a first bit group in the code block. The second bit group is a K^{th} bit group located before the first bit group in the code block, K is an integer greater than or equal to 2. The path selection result includes L paths, and L is an integer greater than or equal to 1. The calculation module 801 is further configured to calculate BMs of the first bit group based on the LLRs. The BMs include L groups of BMs, the L groups of BMs are in a one-to-one correspondence with the L paths, and a quantity of BMs in each group of BMs is 1/L of a total quantity of the BMs. The processing module 802 is configured to select, for each of the L paths, at least L BMs from one group of BMs that corresponds to the path. The processing module 802 further determines path metrics PMs of the first bit group based on the at least L BMs selected for each of the L paths and a path selection result of a previous bit group of the first bit group. The processing module 802 further determines a path selection result of the first bit group based on the PMs.

It can be learned that the calculation module 801 directly obtains the BMs of the first bit group based on the second bit group that is the K^{th} bit group located before the first bit group, where all the BMs of the first bit group are calculated without considering the path selection result of the previous bit group of the first bit group. After obtaining the path selection result of the previous bit group, the processing module 802 can determine the PMs based only on the path selection result of the previous bit group of the first bit group and the selected BMs, where the PMs of the first bit group can be obtained by adding the calculated BMs of the first bit group to PMs of the previous bit group of the first bit group, to determine the path selection result based on the PMs. It can be learned that in an entire decoding process, no PM sorting is required, and when the current bit group is decoded, only the path selection result of the previous bit group needs to be obtained in a PM calculation phase of the current bit group, without waiting for completion of decoding of the previous bit group, so that in the decoding process, other phases before the PM calculation phase can be performed in parallel, thereby greatly reducing a decoding delay, and improving decoding efficiency.

Optionally, each bit group in the code block includes M bits, where M is an integer greater than or equal to 1, and the calculation module 801 is specifically configured to: calculate 2^{KM-K} LLRs of the first bit group that correspond to each of the L paths, where L is 2^{N}, and N is an integer greater than or equal to 0; and calculate L*2^{KM-K} BMs of the first bit group based on the 2^{KM-K} LLRs. For a specific BM calculation manner, refer to the descriptions of step 502 in the embodiment shown in FIG. 5, and details are not described herein again.

Optionally, the processing module 802 is specifically configured to select, for each of the L paths according to a preset rule, the at least L BMs from 2^{KM-K} BMs corresponding to the path. Specifically, for a manner of selecting the at least L BMs, refer to the descriptions of step 503 in the embodiment shown in FIG. 5, and details are not described herein again.

Optionally, the calculation module 801 is specifically configured to:

perform, for each of the L paths, preset sorting on the 2^{KM-K} BMs of the first bit group that correspond to the path or absolute values of the 2^{KM-K} BMs of the first bit group that correspond to the path, and select, according to the preset rule, the L BMs from the BMs on which the preset sorting is performed. Specifically, for a manner of selecting the at least L BMs, refer to the descriptions of step 503 in the embodiment shown in FIG. 5, and details are not described herein again.

Optionally, the processing module 802 is specifically configured to: obtain, for any one of the L paths, at least L PMs by adding the at least L BMs corresponding to the path to PMs of the path; and select, as the PMs of the first bit group according to a preset rule, L PMs from at least L*L PMs corresponding to the L paths. Specifically, for a manner of selecting the at least L PMs, refer to the descriptions of step 504 in the embodiment shown in FIG. 5, and details are not described herein again.

Optionally, the processing module 802 is specifically configured to: group the L*L paths into X path groups; and perform PM comparison on each of the path groups, to obtain L PMs according to the preset rule, where each of the path groups includes 27 paths, and Y is an integer greater than or equal to 0; and select, as the PMs of the first bit group, the L PMs from (L/2^{Y})*L obtained PMs according to the preset rule. Specifically, for a manner of selecting the at least L PMs, refer to the descriptions of step 504 in the embodiment shown in FIG. 5, and details are not described herein again.

Optionally, for the preset rule, selecting X objects from an object set according to the preset rule includes: selecting X maximum objects from the object set; or selecting X minimum objects from the object set; or selecting X objects with maximum absolute values from the object set; or selecting X objects with minimum absolute values from the object set, where the object is a BM or a PM, and X is an integer greater than or equal to 1. For details, refer to the descriptions of step 503 in the embodiment shown in FIG. 5, and details are not described herein again.

Optionally, the second bit group is a start bit group in the code block, and the start bit group is a bit group ranked first in the code block. In this case, specifically, the path selection result of the second bit group is calculated in the following manner: First, the calculation module 801 calculates LLRs of the second bit group; then the calculation module 801 calculates BMs of the second bit group based on the LLRs of the second bit group; afterwards, the processing module 802 selects L BMs from the calculated BMs of the second bit group; next, the processing module 802 calculates PMs of the second bit group based on the L selected BMs; and finally, the processing module 802 determines the path selection result of the second bit group based on the PMs of the second bit group.

It should be noted that this embodiment of this application may also include such an example. In the example, function modules of the decoder such as the calculation module and the processing module may be implemented by using a large scale integrated circuit (Large-scale integrated circuit, LSI for short). The decoder is implemented in a plurality of manners by using the LSI, for example, a digital signal processing (Digital Signal Processing, DSP for short) manner and a field programmable gate array (Field Programmable Gate Array, FPGA for short) manner. In addition, the function modules such as the calculation module and the processing module may be manufactured into individual or separate chips. Certainly, the two function modules may also be manufactured into an individual chip including the two function modules or More function modules. The LSI may be referred to as an integrated circuit (Integrated Circuit, IC for short), a system-level LSI, a very large scale LSI, or an integration-based ultra-large scale LSI.

The decoder in the embodiments of this application is described above. A communications device in the embodiments of this application is described below.

FIG. 9 is a schematic diagram of a communications device according to an embodiment of this application. A communications device 9 is applied to polar code decoding, and the communications device 9 includes a decoder 901 and a transceiver 902 in the embodiment shown in FIG. 9. The transceiver 902 is configured to receive a data stream. The decoder 901 obtains a code block in the data stream and a parameter of the code block. Then the decoder 901 may perform decoding based on the parameter of the code block and the code block, to generate a decoding result. Finally, the decoder 901 outputs the decoding result.

All or some of the foregoing embodiments may be implemented by using software, hardware, firmware, or any combination thereof. When software is used to implement the embodiments, all or some of the embodiments may be implemented in a form of a computer program product.

The computer program product includes one or more computer instructions. When the computer program instructions are loaded and executed on a computer, the procedures or functions according to the embodiments of the present invention are all or partially generated. The computer may be a general-purpose computer, a dedicated computer, a computer network, or another programmable apparatus. The computer instructions may be stored in a computer-readable storage medium or may be transmitted from a computer-readable storage medium to another computer-readable storage medium. For example, the computer instructions may be transmitted from a website, computer, server, or data center to another website, computer, server, or data center in a wired (for example, a coaxial cable, an optical fiber, or a digital subscriber line (DSL)) or wireless (for example, infrared, radio, or microwave) manner. The computer-readable storage medium may be any usable medium accessible by a computer, or a data storage device, such as a server or a data center, integrating one or more usable media. The usable medium may be a magnetic medium (for example, a floppy disk, a hard disk, or a magnetic tape), an optical medium (for example, a DVD), a semiconductor medium (for example, a solid state disk Solid State Disk, SSD for short), or the like.

It may be clearly understood by persons skilled in the art that, for the purpose of convenient and brief description, for a detailed working process of the foregoing system, apparatus, and unit, refer to a corresponding process in the foregoing method embodiments, and details are not described herein again.

In the several embodiments provided in this application, it should be understood that the disclosed system, apparatus, and method may be implemented in other manners. For example, the described apparatus embodiment is merely an example. For example, the unit division is merely logical function division and may be other division in actual implementation. For example, a plurality of units or components may be combined or integrated into another system, or some features may be ignored or not performed. In addition, the displayed or discussed mutual couplings or direct couplings or communication connections may be implemented by using some interfaces. The indirect couplings or communication connections between the apparatuses or units may be implemented in electrical, mechanical, or other forms.

The units described as separate parts may or may not be physically separate, and parts displayed as units may or may not be physical units, may be located in one position, or may be distributed on a plurality of network units. Some or all of the units may be selected according to actual needs to achieve the objectives of the solutions of the embodiments.

In addition, functional units in the embodiments of this application may be integrated into one processing unit, or each of the units may exist alone physically, or two or more units are integrated into one unit. The integrated unit may be implemented in a form of hardware, or may be implemented in a form of a software functional unit.

When the integrated unit is implemented in the form of a software functional unit and sold or used as an independent product, the integrated unit may be stored in a computer-readable storage medium. Based on such an understanding, the technical solutions of this application essentially, or the part contributing to the prior art, or all or some of the technical solutions may be implemented in the form of a software product. The computer software product is stored in a storage medium and includes several instructions for instructing a computer device (which may be a personal computer, a server, a network device, or the like) to perform all or some of the steps of the methods described in the embodiments of this application. The foregoing storage medium includes any medium that can store program code, such as a USB flash drive, a removable hard disk, a read-only memory (ROM), a random access memory (RAM), a magnetic disk, or an optical disc.

The foregoing embodiments are merely intended for describing the technical solutions of this application, but not for limiting this application. Although this application is described in detail with reference to the foregoing embodiments, persons of ordinary skill in the art should understand that they may still make modifications to the technical solutions described in the foregoing embodiments or make equivalent replacements to some technical features thereof, without departing from the spirit and scope of the technical solutions of the embodiments of this application.

1. A polar code decoding method, comprising:
calculating, based on a path selection result of a second bit group in a current code block to be decoded, log-likelihood ratios (LLRs) of a first bit group in the code block, wherein the second bit group is a K^{th} bit group located before the first bit group in the code block, K is an integer greater than or equal to 2, the path selection result comprises L paths, and L is an integer greater than or equal to 1;
calculating branch metrics (BMs) of the first bit group based on the LLRs, wherein the BMs comprise L groups of BMs, the L groups of BMs are in a one-to-one correspondence with the L paths, and a quantity of BMs in each group of BMs is 1/L of a total quantity of the BMs;
selecting, for each of the L paths, at least L BMs from one group of BMs that corresponds to the path;
determining path metrics (PMs) of the first bit group based on the at least L BMs selected for each of the L paths and a path selection result of a previous bit group of the first bit group: and
determining a path selection result of the first bit group based on the PMs.

2. The polar code decoding method according to claim 1, wherein each bit group in the code block comprises M bits, M is an integer greater than or equal to 1, and the calculating LLRs of the first bit group in the code block comprises:
calculating 2^{KM-K} LLRs of the first bit group that correspond to each of the L paths, wherein L is 2^{N}, and N is an integer greater than or equal to 0; and
the calculating BMs of the first bit group based on the LLRs, comprises:
calculating L*2 BMs of the first bit group based on the 2^{KM-K} LLRs corresponding to each of the L paths.

3. The polar code decoding method according to claim 2, wherein the selecting, for each of the L paths, at least L BMs from one group of BMs that corresponds to the path comprises:
selecting, for each of the L paths according to a preset rule, the at least L BMs from 2^{KM-K} BMs corresponding to the path.

4. The polar code decoding method according to claim 3, wherein the selecting, for each of the L paths according to the preset rule, the at least L BMs from 2^{KM-K} BMs corresponding to the path comprises:
sorting, for each of the L paths based on values, the 2^{KM-K} BMs corresponding to the path or absolute values of the 2^{KM-K} BMs corresponding to the path, and selecting the L BMs from the 2^{KM-K} sorted BMs according to the preset rule.

5. The polar code decoding method according to claim 1, wherein the determining PMs of the first bit group based on the at least L BMs selected for each of the L paths and the path selection result of the previous bit group of the first bit group comprises:
obtaining, for any one of the L paths, at least L PMs by adding the at least L BMs corresponding to the path to PMs of the path; and selecting, as the PMs of the first hit group according to a preset rule, L PMs from at least L*L PMs corresponding to the L paths.

6. The polar code decoding method according to claim 5, wherein the selecting, as the PMs of the first bit group according to the preset rule, L PMs from at least L*L PMs corresponding to the L paths comprises:
grouping the at least L*L paths into X path groups, and performing PM comparison on each of the path groups, to obtain the L PMs according to the preset rule, wherein each of the path groups comprises 2^{Y} paths, and is an integer greater than or equal to 0; and
selecting, as the PMs of the first bit group, the L PMs from (L/2^{Y})*L obtained PMs according to the preset rule.

7. The polar code decoding method according to claim 3, wherein the preset rule comprises:
selecting L objects with maximum values from an object set; or
selecting L objects with minimum values from an object set; or
selecting L objects with maximum absolute values from an object set; or
selecting L objects with minimum absolute values from an object set, wherein the object is a BM or a PM.

8. The polar code decoding method according to claim 1, wherein when the second bit group is a start bit group in the code block, the path selection result of the second bit group is
calculated in the following manner
calculating LLRs of the second bit group;
calculating BMs of the second bit group based on the LLRs of the second bit group;
selecting L BMs from the calculated BMs of the second bit group;
calculating PMs of the second bit group based on the L selected BMs: and
determining the path selection result of the second bit group based on the PMs of the second bit group.

9. A decoder applied to polar code decoding, wherein the decoder comprises:
a calculation circuit, configured to calculate, based on a path selection result of a second bit group in a current code block to be decoded, log-likelihood ratios (LLRs) of a first bit group in the code block, wherein the second bit group is a K^{th} bit group located before the first bit group in the code block, K is an integer greater than or equal to 2, the path selection result comprises L paths, and L is an integer greater than or equal to 1, wherein
the calculation circuit is further configured to calculate branch metrics (BMs) of the first bit group based on the LLRs, wherein the BMs comprise L groups of BMs, the L groups of BMs are in a one-to-one correspondence with the L paths, and a quantity of BMs in each group of BMs is 1/L of a total quantity of the BMs; and
a processing circuit, configured to select, for each of the L paths, at least L BMs from one group of BMs that corresponds to the path, wherein
the processing circuit is further configured to determine path metrics (Ms) of the first bit group based on the at least L BMs selected for each of the L paths and a path selection result of a previous bit group of the first bit group; and
the processing circuit is further configured to determine a path selection result of the first bit group based on the PMs.

10. The decoder according to claim 9, wherein each bit group in the code block comprises M bits, M is an integer greater than or equal to 1, and the calculation circuit is configured to:
calculate 2^{KM-K} LLRs of the first bit group that correspond to each of the L paths, wherein L is 2^{N}, and N is an integer greater than or equal to 0; and
calculate L*2^{KM-K} BMs of the first bit group based on the 2^{KM-K} LLRs.

11. The decoder according to claim 10, wherein the processing circuit is configured to:
select, for each of the L paths according to a preset rule, the at least L BMs from 9^{KM-K} BMs corresponding to the path.

12. The decoder according to claim 11, wherein the calculation circuit is configured to:
perform, for each of the L paths, preset sorting on the 2^{KM-K} BMs that are in the BMs of the first bit group and that correspond to the path or absolute values of the 2^{KM-K} BMs that are in the BMs of the first bit group and that correspond to the path, and select, according to the preset rule, the L BMs from the 2^{KM-K} BMs on which the preset soiling is performed.

13. The decoder according to claim 9, wherein the processing circuit is configured to:
obtain, for any one of the L paths, at least L PMs by adding the at least L BMs corresponding to the path to PMs of the path; and select, as the PMs of the first bit group according to a preset rule, L PMs from at least L*L PMs corresponding to the L paths.

14. The decoder according to claim 13, wherein the processing circuit is configured to:
group the at least L*L paths into X path groups, and perform PM comparison on each of the path groups, to obtain the L PMs according to the preset rule, wherein each of the path groups comprises 2^{Y} paths, and Y is an integer greater than or equal to 0; and
select, as the PMs of the first bit group, the L PMs from (L/2^{Y} )*L obtained PMs according to the preset rule.

15. The decoder according to claim 11, wherein the preset rule comprises:
selecting L objects with maximum values from an object set; or
selecting L objects with minimum values from an object set; or
selecting L objects with maximum absolute values from an object set; or
selecting L objects with minimum absolute values from an object set, wherein the object is a BM or a PM.

16. The decoder according to claim 9, wherein when the second bit group is a start bit group in the code block, the path selection result of the second bit group is calculated in the following manner:
the calculation circuit is configured to calculate LLRs of the second bit group;
the calculation circuit is further configured to calculate BMs of the second bit group based on the LLRs of the second bit group;
the processing circuit is configured to select L BMs from the calculated BMs of the second bit group;
the processing circuit is further configured to calculate PMs of the second bit group based on the L selected BMs; and
the processing circuit is further configured to determine the path selection result of the second bit group based on the PMs of the second bit group.

17. A communications device, wherein the communications device comprises a transceiver and the decoder according to claim 9;
the transceiver is configured to receive a data stream;
the decoder obtains a code block in the data stream and a parameter of the code block;
the decoder performs decoding based on the parameter of the code block and the code block, to generate a decoding result; and
the decoder outputs the decoding result.

18. A non-transitory computer-readable storage medium, comprising an instruction, wherein when the instruction runs on a computer, the computer performs the method according to claim 1.

19. A computer program product comprising an instruction, wherein when the instruction runs on a computer, the computer performs the method according to claim 1.
